(19) United States
(12) Patent Application Publication
(10) Pub. No.: US 2025/0211103 A1
(43) Pub. Date: Jun. 26, 2025

(54) SWITCHED CAPACITOR CONVERTER AND POWER CONVERTER

(71) Applicant: Infineon Technologies AG, Neubiberg (DE)

(72) Inventor: Peter Bogner, Wernberg (AT)

(21) Appl. No.: 18/981,808

(22) Filed: Dec. 16, 2024

(30) Foreign Application Priority Data
Dec. 20, 2023 (DE) 10 2023 136 039.6

(51) Int. Cl. H02M 3/07; H02M 3/158; H03M 1/80

(52) U.S. Cl. CPC H02M 3/07; H02M 3/158; H03M 1/804

(57) ABSTRACT

A switched capacitor converter can comprise an input pad for applying an analog input voltage; an input capacitor, the first terminal of which is continuously electrically conductively connected to the input pad and the second terminal of which is electrically conductively connected to an input of an amplifier; the amplifier; and a switched capacitor circuit, which is electrically conductively connected to the amplifier input on the one hand, and can be switched between a reference potential and a predefined reference voltage on the other.

### REFERENCE TO RELATED APPLICATIONS

This application claims priority to German Patent Application 10 2023 136 039.6, filed on Dec. 20, 2023, the contents of which are hereby incorporated by reference in their entirety.

### TECHNICAL FIELD

The invention relates to switched capacitor converters and a power converter.

### BACKGROUND

Switched power supplies for power converters, such as DC/DC converters, are usually implemented by current control loops. The output voltage is kept constant while the current in the power converter, for example in the DC/DC converter, is controlled. For this purpose, the current and voltages in the converter must be measured.

Typically, the input and output voltage of a power converter is higher than the supply voltage of a control chip. Therefore, from the point of view of the control chip, these voltages are referred to as high voltage. The same applies to current that can be measured via a so-called shunt resistor (in this case, the common mode voltage can be higher than the supply voltage used). The shunt resistor can be undefined, e.g. floating, in the inner nodes of the power converter, for example the DC/DC converter.

The measurement of voltages and currents must be converted to digital format. In modern systems, control loops are usually implemented in a digital controller. Therefore, a comparator or an analog-to-digital converter is usually required in such circuits.

One problem is measuring a current ramp that exceeds a threshold. Once the threshold is reached, the power transistor of a power converter should be switched. This exceeding of the threshold should be detected with low, if any, latency and a high degree of accuracy. The threshold should be configurable, and in some applications, the threshold should be adjustable during the measurement.

### SUMMARY

Conventional DC-DC converters typically use a time-continuous comparator. The reference of the time-continuous comparator is derived from a digital-to-analog converter (DAC).

However, this implementation has several drawbacks:
in the case of high-accuracy requirements, a time-continuous comparator is space-intensive (the offset of the comparator is determined by the transistor size);
a time-continuous comparator consumes a lot of power at high speed;
a resistor divider can be required to direct the high voltage into the supply area of the device; this ohmic input permanently loads the measuring path and generates voltage drops along the line resistances;
the DAC is usually implemented in continuous time and requires more space than a comparable DAC with switched capacitors; and
in the case of highly accurate measurements, continuous time measurements suffer from flicker noise (low-frequency noise).

### BRIEF DESCRIPTION OF THE DRAWINGS

Exemplary embodiments of the invention are illustrated in the figures and are explained in more detail below.

In the figures:

FIG. 1 shows a power converter comprising a switched capacitor converter, for example, comprising an analog-to-digital converter according to various aspects of this disclosure;

FIG. 2 shows the power converter comprising a switched capacitor converter, for example comprising an analog-to-digital converter from FIG. 1, in greater detail;

FIG. 3 shows a timing diagram of a synchronized comparator according to various aspects of this disclosure;

FIG. 4 shows an exemplary representation of the temporal profile of an input voltage and a detection of a comparator; and

FIG. 5 shows a power converter comprising a switched capacitor converter, for example, comprising an analog-to-digital converter according to various aspects of this disclosure.

### DETAILED DESCRIPTION

In the following detailed description, reference is made to the accompanying drawings, which form part of said description and in which specific embodiments in which the invention may be carried out are shown for illustrative purposes. In this respect, directional terminology such as “top”, “bottom”, “at the front”, “at the rear”, “front”, “rear”, etc. is used with reference to the orientation of the described figure(s). Since components of embodiments may be positioned in a number of different orientations, the directional terminology is used for illustrative purposes and is in no way limiting. It goes without saying that other embodiments may be used and structural or logical changes may be made without departing from the scope of protection of the present invention. It goes without saying that the features of the various exemplary embodiments described herein may be combined with one another, unless specifically indicated otherwise. The following detailed description should therefore not be interpreted in a restrictive sense, and the scope of protection of the present invention is defined by the appended claims.

For the purposes of this description, the terms “connected” and “coupled” are used to describe both a direct and an indirect connection, as well as a direct or indirect coupling. In the figures, identical or similar elements are labeled with identical reference signs, where this is appropriate.

As an illustration, various aspects of this disclosure demonstrate the use of a switched capacitor implementation of a comparator and a digital-to-analog converter (DAC) for a switched capacitor converter, for example, for an analog-to-digital converter, for example, for a power converter.

In a conventional DC-DC converter, an analog input switch is provided, which is connected between an input pad and an input capacitor of the switched capacitor converter, for example the analog-to-digital converter. However, such an analog (high voltage) input switch is a difficult or sometimes impossible design requirement in some applications.

An analog input switch provided in such a conventional implementation between an input pad and an input capacitor of the switched capacitor converter, for example, of the analog-to-digital converter, is no longer provided in various aspects of this disclosure.

In combination with a switched-mode power supply, in various aspects of this disclosure it is provided for illustrative purposes to synchronize the switching of a power MOSFET (metal oxide semiconductor field-effect transistor), for example a power converter, with a measuring unit (e.g. a switched capacitor converter, e.g. an analog-to-digital converter). This enables the entire switched capacitor converter, for example the entire analog-to-digital converter, to be initialized exactly at the switching point of the power converter. The measurement is thus reduced to a radiometric measurement or a delta measurement, wherein the switching point of the power MOSFET is defined as a reference (or a phase-shifted point in time).

Although a DC-DC converter is described below as an example of a power converter in a very simple configuration, it should be noted that various aspects of this disclosure are not limited to a DC-DC converter (DC voltage converter). Various aspects of a switched capacitor converter, e.g. an analog-to-digital converter, can be used in any power converter, for example any switched power converter (e.g. also an AC-DC converter). The exact architecture of the power converter is also irrelevant. Thus, the switched capacitor converter, e.g. the analog-to-digital converter according to various aspects can be used, for example, in a power converter without galvanic isolation, for example in a DC-DC converter of various topologies, for example in a step-down converter, a step-up converter, an inverse converter, a synchronous converter, a SEPIC converter, a Cuk converter, a Zeta converter, a double inverter, a split-Pi converter, a cascaded step-down converter or a cascaded step-up converter, and the like. Furthermore, the switched capacitor converter, e.g. the analog-to-digital converter according to various aspects can be used, for example, in a power converter with galvanic isolation, for example in a DC-DC converter of various topologies, for example in a blocking converter, a forward converter, a push-pull converter, a resonant converter or a bridgeless PFC converter.

As an illustration, a measuring unit comprising a switched capacitor circuit is provided in various aspects in which the input capacitor is not switched between an input voltage of the switched capacitor converter, e.g. the analog-digital converter and an (e.g. negative) input reference voltage. The input capacitor is constantly connected to the input voltage of the switched capacitor converter, e.g. the analog-to-digital converter. The set threshold refers to the input voltage level at the end of an initialization phase. The threshold is determined by a reference voltage VAREF and the ratio of the capacitance Ci of the input capacitor to the sum of capacitances of switched capacitors CR0 to CRN of a switched capacitor (SC) circuit, as will be explained further below. The measurement is a continuous time measurement without any switching delay. The delay in signal processing is only provided by the speed of the analog comparator module in the switched capacitor converter, e.g. the analog-to-digital converter.

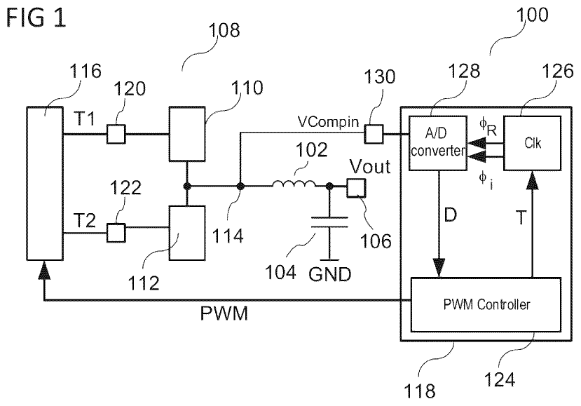

FIG. 1 shows a DC-DC converter 100 as an example of a power converter having a switched capacitor converter (in this example an analog-to-digital converter 128) according to various aspects of this disclosure.

The DC-DC converter 100 has an inductor 102, for example a coil 102, and a capacitor 104. A first terminal of the inductor 102 is connected to a first terminal of the capacitor 104, the second terminal of the capacitor is connected to a reference potential, for example the ground potential GND. Furthermore, the first terminal of the inductor 102 is connected to an output terminal (e.g. an output pad) 106 of the DC-DC converter 100, on which an output voltage Vout of the DC-DC converter 100 is provided.

Furthermore, a bridge circuit 108 is provided, in this example a half-bridge circuit having a first power transistor 110 and a second power transistor 112.

A second terminal of the inductor 102 is directly connected to an intermediate node 114 of the bridge circuit and is thus on the same electrical potential. The intermediate node 114 is a node that connects the first power transistor 110 to the second power transistor 112.

Furthermore, the DC-DC converter 100 has a gate driver circuit 116 and a controller chip 118. The gate driver circuit 116 provides the power transistors 110, 112 with gate driver signals T1, T2; a first gate driver signal T1 at a gate terminal 120 of the first power transistor 110, and a second gate driver signal T2 at a gate terminal 122 of the second power transistor 112.

The controller chip 118 comprises a pulse width modulation (PWM) controller 124, a clock signal generator 126 and an analog-to-digital converter 128. The controller chip 118 further comprises an input pad 130, which is electrically conductively connected to the analog-to-digital converter 128. The structure of the analog-to-digital converter 128 is explained in more detail below. The input pad 130 is directly connected to the intermediate node 114 of the bridge circuit 108 and is thus on the same electrical potential VCompin. The analog-to-digital converter 128 receives the analog electrical potential VCompin and converts this analog potential into a digital signal, for example a digital value (such as a binary value) D and delivers this to an input of the PWM controller 124. The PWM controller 124 generates a pulse width modulation control signal PWM depending on the received digital value D and thereby controls the gate driver circuit 116. Furthermore, the PWM controller 124 generates a clock generator control signal T and thereby controls the clock signal generator 126. The clock signal generator 126 in turn receives the clock generator control signal T and uses this to generate various clock signals (e.g. a first clock signal ΦR and a second clock signal Φi) for controlling various switches of the analog-to-digital converter 128 (e.g. the switched capacitor circuit). The analog-to-digital converter 128 can, as will be explained in more detail below, have a switched capacitor circuit, e.g. switched capacitor circuit 208.

The controller chip 118 can have all its components monolithically integrated on a common chip. Alternatively, however, the pulse width modulation (PWM) controller 124 and the analog-to-digital converter 128 can also be separate chips connected to each other.

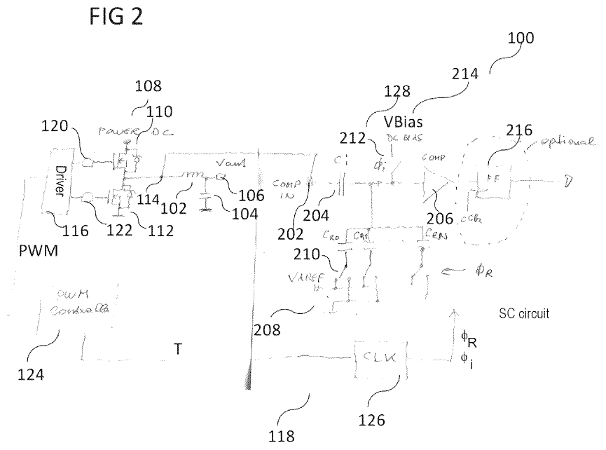

FIG. 2 shows the DC-DC converter 100 in greater detail. In this example, bridge circuit 108 has a first n-channel MOSFET as the first power transistor 110 and a second n-channel MOSFET as the second power transistor 112. In alternative implementations, power transistors 110, 112 can also be configured as p-channel MOSFETs or as any other suitable transistors.

The analog-to-digital converter 128 can comprise an input pad 202 (which can be the same pad as the input pad 130), as well as an input capacitor 204, an amplifier (for example, additionally a latch connected to the amplifier to form a comparator) 206, and a switched capacitor circuit 208 (also referred to as an SC circuit). A first terminal of the input capacitor 204 is continuously electrically conductively connected to the input pad 202, in other words permanently firmly connected such that the electrical potential VCompin present at the input pad 202 is always substantially also present at the first terminal of the input capacitor 204. In other words, the connection between the first terminal of the input capacitor 204 and the input pad 202 is switch-free as it is provided on-chip in a conventional analog-to-digital converter, as explained above. A power transistor, for example the second power transistor 112, of the bridge circuit 108, is used, in simple terms, as a “switch replacement” in various aspects of this disclosure. Generally, according to various aspects of this disclosure, any chip-external switch can be used as a replacement for the conventional chip-internal input switch, which, as will be explained further below, is correspondingly synchronized with a switched capacitor circuit 208 of the analog-to-digital converter 128 to provide, for example, in an initialization phase, a defined electrical potential (for example, a fixed reference potential) at the input pad 130, 202 of the analog-to-digital converter 128. In this context, chip-external means external to a chip in which the analog-to-digital converter 128 is monolithically integrated. In the case that the analog-to-digital converter 128 is integrated in the controller chip 118 together with the pulse width modulation (PWM) controller 124, chip-external means that the switch is arranged outside of the controller chip 118. In the case that the analog-to-digital converter 128 is integrated on its own chip separately from the pulse width modulation (PWM) controller 124, chip-external means that the switch is arranged outside of the so-called analog-to-digital converter chip.

It should be noted that in some aspects of this disclosure, the input capacitor 202 can also be chip-externally arranged. In this case, the input capacitor 202 is part of the analog-to-digital converter, but it is not part of the chip in which the rest of the analog-to-digital converter is implemented.

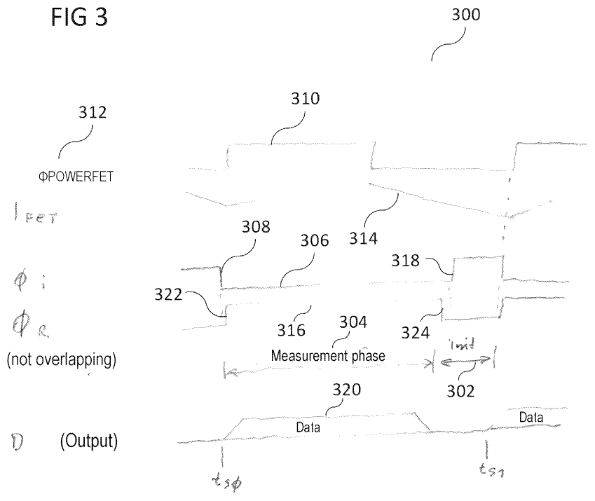

The power transistors, such as the first power transistor 110 and the second power transistor 112, ensure that at the intermediate node 114, for example, at the end of an initialization phase of the analog-to-digital converter 128, a defined potential is present, for example, no current IFET flows through the inductor 102 (see, for example, temporal profile 314 of the coil current IFET in FIG. 3). This is provided, for example, when the first power transistor 110 is switched in a blocking manner, that is, electrically non-conductively, and the second power transistor 112 is electrically conductively switched and a fixed known electrical potential has formed at the intermediate node 114 in an equilibrium state (in this case, the electrical potential at the intermediate node 114, for example, is a fixed reference potential, in this example the ground potential). A second terminal of the input capacitor 204 is electrically conductively connected to an amplifier input (for example, additionally to a latch which is connected to the amplifier to form a comparator) 206. As an alternative to the intermediate node 114, the input pad can also be electrically conductively connected to a node on the other side of the inductor 102, i.e., for example, to a node which is located between the first terminal of the inductor 102 and the output pad 106. Also at this node, a known electrical potential can form in the equilibrium state of the inductor 102.

The analog-to-digital converter 128 can further comprise a switched capacitor circuit 208, which is electrically conductively connected to the amplifier input (for example comparator) 206 on the one hand, and which can be switched between a reference potential (e.g. ground potential GND) and a predefined reference voltage VAREF on the other. The switched capacitor circuit 208 can be a series circuit or several series circuits each of a capacitor CR0, CR1, . . . , CRN (with N of any integer, for example N=0 to 100, for example N=0 to 20, for example N=0 to 10) and a switch 210. The clock signal generator 126 generates, for example, the first clock signal ΦR and thereby controls the one or more switches 210 and switches this/these between a first switch position, in which the respective switch 210 connects the respective capacitor CR0, CR1, . . . , CRN to the reference potential (e.g. in an initialization phase of the analog-to-digital converter 128), and a second switch position in which the respective switch 210 connects the respective capacitor CR0, CR1, . . . , CRN to the reference voltage VAREF (e.g. in a measuring phase of the analog-to-digital converter 128). If several series circuits are provided in the switched capacitor circuit 208, then the series circuits are connected to each other in parallel.

It should be noted that the clock signal generator (e.g. 126) can be located at any position within the analog-to-digital converter (generally at any position within the switched capacitor converter).

The analog-to-digital converter 128 can further comprise a bias voltage switch 212, which is connected between the amplifier input (for example comparator) 206 and a bias voltage terminal 214 and is set up to receive a bias voltage VBias (also referred to as initialization voltage, neutral voltage or DC voltage). The PWM controller 124 can (as an example of a first switch controller) control the bias voltage switch 212 by means of the clock generator 126 such that it closes the bias voltage switch 212 in an initialization phase 302 (see FIG. 3), so that the bias voltage VBias is applied to the amplifier input (for example comparator) 206, and such that it opens the bias voltage switch 212 in a measuring phase 304 of the bias voltage switch, so that the amplifier input (for example comparator) 206 is isolated from the bias voltage VBias.

The analog-to-digital converter 128 can optionally also have a memory element 216, which is connected to an output of the amplifier (for example comparator) 206 for storing the digital signal D output by the amplifier (for example comparator) 206. The memory element 216 can be, or have, a flip-flop, for example a D-flip-flop. The optional memory element 216 (e.g. flip-flop 216) can be provided at the output of the amplifier (e.g. comparator) 206 in order to re-synchronize the analog output of the amplifier (e.g. comparator) 206.

In the following, the function of the analog-to-digital converter 128 is explained in more detail using a timing diagram 300, which can be seen in FIG. 3.

The clock signal generator 126 generates the first clock signal Φi and thereby controls the bias voltage switch 212, for example in such a way that an initialization phase of the analog-to-digital converter 128 (in which the bias voltage switch 212 is closed, in other words, conductively switched) is terminated with the opening (in other words, blocking) of the bias voltage switch 212, for example, by bringing the first clock signal Φi from a first state (e.g. logically “ON”) to a second state (e.g. logically “OFF”) (see the falling edge 308 in the temporal profile 306 of the first clock signal Φi). This switching is synchronized with the corresponding switching of the chip-external switch, for example the second power transistor 112 (see temporal profile 312 of a power transistor switching signal ΦPOWERFET 310, with which the second power transistor 112 is controlled (the circuit-breaker switching signal ΦPOWERFET 310 can be applied to the gate of the second power transistor 112)) such that, in the initialization phase 302, the first power transistor 110 is opened (i.e. not conductively switched) and the second power transistor 112 is closed (i.e. conductively switched), wherein the first power transistor 110 is closed synchronously with the end of the initialization phase 302 and thus with the start of the measuring phase 304 (and is thus conductively switched) and the second power transistor 112 is opened (and thus switched to a blocking state). FIG. 3 shows a corresponding exemplary curve 314 of a coil current IFET flowing through the inductor, for example the coil 102. At the end of measuring phase 304, the first clock signal Φi switches back from the second state to the first state (logically “ON”) (see rising edge 318 in the temporal profile 306 of the first clock signal Φi).

It should be noted that the clock signal generator 126 does not generate the first clock signal Φi and the second clock signal ΦR at the same time and the respective clock edges are not applied at the same time, but with a small time offset in a range of e.g. a few ns, e.g. in a range of 2 to 10 ns, to the bias voltage switch 212 or to the switches 210. For example, the rising edge of the second clock signal ΦR applied to the one or more switches 210 can be applied at the small time offset after the falling edge of the first clock signal Φi applied to the bias voltage switch 212.

During the initialization phase 302, the reference point to which the programmed threshold value for amplifier (for example comparator) 206 refers is specified. In the initialization phase 302, the switched capacitor circuit 208 (also referred to as the switched capacitor digital-to-analog converter, SC-DAC) is also initialized by switching, in other words applying, all of one or more (DAC) capacitors CR0, CR1, . . . , CRN to the reference potential (for example, ground potential). The input node (also referred to as the input) of the amplifier (for example comparator) 206 is connected to any DC bias voltage (for example, the bias voltage VBias) with low resistance (for example, by means of the bias voltage switch 212). The bias voltage VBias is not responsible for the threshold setting and is cancelled by the SC switching scheme. The bias voltage VBias only defines a suitable bias voltage point for the amplifier (for example comparator) 206.

After the initialization phase 302, the threshold is applied to the amplifier (for example comparator) 206 by the PWM controller 124 and/or the clock signal generator 126 (as an example of a second switch controller) switching at least one capacitor of one or more capacitors CR0, CR1, . . . , CRN from the reference potential GND to a predefined (internal) reference voltage VAREF by means of the second clock signal ΦR (see temporal profile 316 of the second clock signal ΦR in FIG. 3). The second clock signal ΦR is temporally synchronized (in other words essentially simultaneously) with the circuit breaker switching signal ΦPOWERFET 312 and the first clock signal Φi (however, with a small time offset, as explained above) (see the rising edge 322 of the temporal profile 316 of the second clock signal ΦR in FIG. 3, with which the one or more switches 210 are switched from a second state (logically “OFF”) to a first state (logically “ON”) (at the end of a respective initialization phase 302 and the start of a respective measuring phase 304), and the falling edge 324 of the temporal profile 316 of the second clock signal ΦR in FIG. 3, with which the one or more switches 210 are switched from the first state (logically “ON”) to the second state (logically “OFF”) (at the end of a respective measuring phase 304 and the beginning of a respective initialization phase 302)).

It should be noted that the input voltage of the amplifier (for example comparator) 206 is not switched at all and is always present at the amplifier input (for example comparator) 206. However, the VAREF reference voltage is changed by the one or more switches 210 of the switched capacitor circuit 208 (reference DAC 208).

In other words, the threshold value of the amplifier (for example comparator) 206 is defined by a delta to the input voltage (or input current) present at the amplifier input (for example comparator) 206 at the end of the initialization phase 302.

The input voltage of the amplifier (e.g. comparator) 206 changes after the initialization time (the end of initialization phase 302). The amplifier (for example comparator) 206 now continuously tracks the input voltage (the amplifier input (for example comparator) is no longer connected to a bias voltage VBias). If the input voltage of the amplifier (e.g. comparator) 206 exceeds the selected threshold voltage (selected by the one or more switches 210 and thus the one or more capacitors CR0, CR1, . . . , CRN) (for example, the size of the one or more capacitors CR0, CR1, . . . , CRN, illustrative of the capacitance of the one or more capacitors of the connected one or more capacitors CR0, CR1, . . . , CRN), the amplifier input (for example comparator) 206 changes the sign and the output of the amplifier (for example comparator) 206 generates a digital bit change at the digital signal D that is output and thus provided by the amplifier (for example comparator) 206 (see temporal profile 320 of the digital signal D in FIG. 3).

Again, referring to FIG. 3, ΦPOWERFET illustrates the switching point of the power transistor, for example, the first power transistor 110 in the DC/DC converter 100 and IFET the coil current flowing through the coil 102.

The first clock signal Φi controls the bias voltage switch 212 and the second clock signal ΦR switches the one or more switches 210 of the switched capacitor circuit 208. The first clock signal Φi and the second clock signal ΦR are kept synchronous for switching the power transistors, for example, the first power transistor 110 and the second power transistor 112. While the first clock signal is a state Φi=logical “0”, the amplifier input (for example comparator) 206 tracks the input voltage and provides information if the input voltage changes by more than the set threshold.

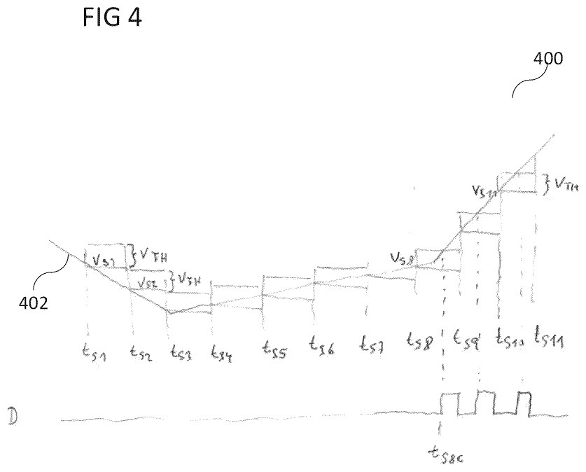

FIG. 4 shows a temporal profile 402 of an input voltage in a diagram 400 by way of example. Normally, the input voltage (current) increases or decreases with each switching point. Ts1, ts2, . . . , tsn (with n of any integer, for example n=11) define all the initialization points. A decreasing input voltage (valid for switching times ts1 and ts2) will never exceed the sampled input voltage Vs1 plus the set threshold voltage VTH.

Switching times ts3 to ts7 see an increasing input voltage, but the voltage change is too small to exceed the sampled voltages+VTH. No toggling of the amplifier (comparator) output is triggered.

The switching times ts8 to ts11 show a transition of the sampled voltage+VTH. For example, at the switching time Ts8, an input voltage of Vs8 is sampled. At the switching time Ts8c, the input voltage exceeds the sampled voltage+VTH and the amplifier (comparator) output reports this event to the digital controller by means of the digital signal D.

At the next initialization point (ts9), the output of the amplifier (for example comparator) 206 is reset to “0”.

The value of the threshold voltage of the amplifier (for example comparator) 206 is thus set, in simple terms, by:
the ratio of the capacitance Ci of the input capacitor 204 to the sum of the capacitances of the one or more switched capacitors CR0, CR1, . . . , CRN; and
the value of the reference voltage VAREF.

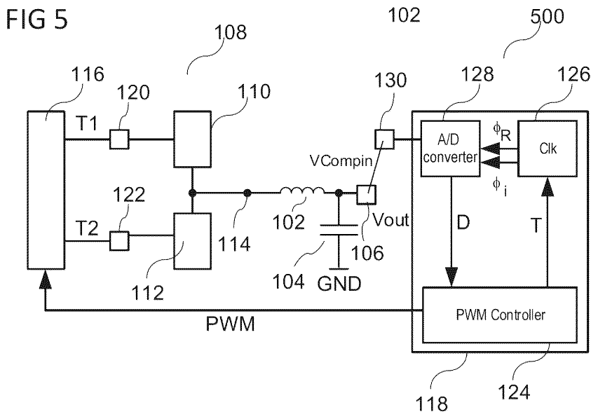

FIG. 5 shows a DC-DC converter 500 as an example of a power converter comprising an analog-to-digital converter 128 according to various aspects of this disclosure.

The DC-DC converter 500 according to FIG. 5 is very similar to the DC-DC converter 100 according to FIG. 1, however, the input pad 130 is not connected to the intermediate node 114 of the bridge circuit 108, but is directly connected to the output terminal (e.g. the output pad) 106 of the DC-DC converter 500. Thus, the output voltage Vout provided at the output terminal (e.g. the output pad) 106 of the DC-DC converter 500 is equal to the electrical potential VCompin, which the analog-to-digital converter 128 receives and converts into a digital signal and delivers this to the PWM controller 124 input.

Various aspects of this disclosure have all the effects of circuits with switched capacitors, such as correlated double sampling, which eliminates the amplifier (comparator) offset, and high speed combined with a high degree of accuracy over a small area.

Various aspects of this disclosure also have the effect that, in addition to the input capacitor 204, no single high-voltage component is required on the chip of the analog-to-digital converter 128 (for example, the controller chip 118). The input capacitor 204 can be implemented as a metallic/insulation/metal capacitor and can therefore withstand much more voltage than the other parts of the circuit. As shown in FIG. 2, there is no switch between the input pad 202 of the analog-to-digital converter 128 and the input capacitor 204. In practice, the input voltage can be larger than the supply voltage of the controller (or the microchip in which this circuit is implemented).

Various aspects of this disclosure allow a radiometric voltage measurement based on an input voltage present at a known point in time (the end of the initialization phase 302).

Different aspects can provide only a single switched (reference) capacitor or also several capacitors CR0, CR1, . . . , CRN. Only one threshold can be set for a single switched (reference) capacitor. If several capacitors CR0, CR1, . . . , CRN are provided, several threshold values can be set depending on which of the several capacitors CR0, CR1, . . . , CRN are switched. For example, a DAC 208 with e.g. 10 bits can be provided. If the capacitors CR0, CR1, . . . , CRN are binary scaled, this results in 10 capacitors CR0, CR1, . . . , CR9. It is also possible to implement the DAC 208 with thermometer code, which would result in 1024 capacitors CR0, CR1, . . . , CR1023. This is possible with traditional CMOS technology and offers a perfect differential non-linearity.

Digital designs can be implemented with synchronous logic that uses a clock generator. A flip-flop at the output of the amplifier (for example comparator) is therefore advantageous. This leads to an additional delay, but is an interface to the digital circuit, which can be downstream of the amplifier (e.g. comparator) 206.

In the following, examples of various other aspects of this disclosure are explained.

Example 1 is a switched capacitor converter (e.g. analog-to-digital converter). The switched capacitor converter (e.g. analog-digital converter) can comprise: an input pad for applying an analog input voltage; an input capacitor, the first terminal of which is continuously electrically conductively connected to the input pad and the second terminal of which is electrically conductively connected to an input of an amplifier (e.g. comparator); the amplifier (e.g. comparator); and a switched capacitor circuit, which is electrically conductively connected to the amplifier input (for example comparator) on the one hand, and can be switched between a reference potential and a predefined reference voltage on the other.

In Example 2, the subject matter of Example 1 can optionally provide that there is a switch-free connection between the first terminal of the input capacitor and the input pad.

In Example 3, the subject matter of any of Examples 1 or 2 can optionally provide that the switched capacitor circuit is synchronized with the input voltage curve.

In Example 4, the subject matter of any of Examples 1 to 3 can optionally provide that the input voltage depends on a voltage at a power field-effect transistor of a switched power converter circuit.

In Example 5, the subject matter of any of Examples 1 to 4 can optionally provide that the switched capacitor converter (e.g. analog-digital converter) further comprises a bias voltage switch which is connected between the amplifier input (e.g. comparator) and a bias voltage terminal and is set up to receive a bias voltage.

In Example 6, the subject matter of Example 5 can optionally provide that the switched capacitor converter (e.g. analog-digital converter) further comprises a first switch controller, which is set up to close the bias voltage switch in an initialization phase, so that the bias voltage is applied to the amplifier input (e.g. comparator), and to open the bias voltage switch in a measuring phase, so that the amplifier input (for example comparator) is isolated from the bias voltage.

In Example 7, the subject matter of any of Examples 1 to 6 can optionally provide that the switched capacitor converter (e.g. analog-digital converter) further comprises a second switch controller, which is set up to switch the switched capacitor circuit for setting a threshold voltage of the amplifier (e.g. comparator).

In Example 8, the subject matter of Example 7 can optionally provide that the second switch controller is set up to connect the switched capacitor circuit to the reference potential in an initialization phase and to connect the switched capacitor circuit to the reference voltage in a measuring phase.

In Example 9, the subject matter of any of Examples 7 or 8 can optionally provide that the second switch controller is set up to provide the input voltage according to an equilibrium state of a power field-effect transistor of a switched power converter circuit, so that in a first equilibrium state of the power field-effect transistor, the switched capacitor circuit is connected to the reference potential and that in a second equilibrium state of the power field-effect transistor, the switched capacitor circuit is connected to the reference voltage.

In Example 10, the subject matter of any of Examples 8 and 9 can optionally provide that the second switch controller is set up to terminate an initialization phase of the switched capacitor circuit and to start the measuring phase synchronously with the second equilibrium state of the power field-effect transistor in which the power field-effect transistor is conductively switched.

In Example 11, the subject matter of any of Examples 1 to 10 can optionally provide that the switched capacitor converter (e.g. analog-digital converter) further comprises a memory element which is connected to an output of the amplifier (e.g. comparator) for storing a digital signal output from the amplifier (e.g. comparator).

In Example 12, the subject matter of any of Examples 1 to 11 can optionally provide that the switched capacitor circuit has at least one capacitor and a switch, wherein a first terminal is connected to the amplifier input (for example comparator) and a second terminal is connected to the switch, wherein the switch can be switched between the reference potential and the reference voltage.

Example 13 is a switched capacitor converter (e.g. analog-to-digital converter). The switched capacitor converter (e.g. analog-to-digital converter) can comprise an amplifier (e.g. comparator); an input capacitor connected to the amplifier (e.g. comparator) on the input side, which is further connected to an analog input voltage; and a switched capacitor circuit, which is connected to the amplifier input (for example comparator) on the one hand, and can be switched between a reference potential and a predefined reference voltage on the other; wherein the switched capacitor circuit is set up to switch depending on a voltage curve at a power field-effect transistor of a switched power converter circuit.

In Example 14, the subject matter of Example 13 can optionally provide that the switched capacitor converter (e.g. analog-digital converter) further comprises an input pad for applying an analog input voltage, wherein a first terminal of the input capacitor is continuously electrically conductively connected to the input pad, and wherein a second terminal of the input capacitor is electrically conductively connected to an amplifier input (for example comparator).

In Example 15, the subject matter of Example 14 can optionally have a switch-free connection between the first terminal of the input capacitor and the input pad.

In Example 16, the subject matter of any of Examples 13 to 15 can optionally provide that the switched capacitor circuit is set up to switch synchronously with the voltage curve of the voltage at the power field-effect transistor.

In Example 17, the subject matter of any of Examples 13 to 16 can optionally provide that the switched capacitor converter (e.g. analog-digital converter) further comprises a bias voltage switch which is connected between an amplifier input (e.g. comparator) and a bias voltage terminal and is set up to receive a bias voltage.

In Example 18, the subject matter of Example 17 can optionally provide that the switched capacitor converter (e.g. analog-digital converter) further comprises a first switch controller, which is set up to close the bias voltage switch in an initialization phase, so that the bias voltage is applied to the amplifier input (e.g. comparator), and to open the bias voltage switch in a measuring phase, so that the amplifier input (for example comparator) is isolated from the bias voltage.

In Example 19, the subject matter of any of Examples 13 to 18 can optionally provide that the switched capacitor converter (e.g. analog-digital converter) further comprises a second switch controller, which is set up to switch the switched capacitor circuit for setting a threshold voltage of the amplifier (e.g. comparator).

In Example 20, the subject matter of Example 19 can optionally provide that the second switch controller is set up to connect the switched capacitor circuit to the reference potential in an initialization phase and to connect the switched capacitor circuit to the reference voltage in a measuring phase.

In Example 21, the subject matter of any of the Examples 19 or 20 can optionally provide that the second switch controller is set up to provide the input voltage according to an equilibrium state of the power field-effect transistor, so that in a first equilibrium state of the power field-effect transistor, the switched capacitor circuit is connected to the reference potential and that in a second equilibrium state of the power field-effect transistor, the switched capacitor circuit is connected to the reference voltage.

In Example 22, the subject matter of Example 20 and 21 can optionally provide that the second switch controller is set up to terminate an initialization phase of the switched capacitor circuit and to start the measuring phase synchronously with the second equilibrium state of the power field-effect transistor in which the power field-effect transistor is conductively switched.

In Example 23, the subject matter of any of Examples 13 to 22 can optionally provide that the switched capacitor converter (e.g. analog-digital converter) further comprises a memory element which is connected to an output of the amplifier (e.g. comparator) for storing a digital signal output from the amplifier (e.g. comparator).

In Example 24, the subject matter of any of the Examples 13 to 23 can optionally provide that the switched capacitor circuit has at least one capacitor and a switch, wherein a first terminal is connected to an amplifier input (for example comparator) and a second terminal is connected to the switch, wherein the switch can be switched between a reference potential and the reference voltage.

Example 25 is a switched capacitor converter (e.g. analog-to-digital converter). The switched capacitor converter (e.g. analog-to-digital converter) can comprise an amplifier (e.g. comparator); an input capacitor connected to the amplifier (e.g. comparator) on the input side, which is further connected to an analog input voltage by means of an input switch; and a switched capacitor circuit, which is connected to the amplifier input (for example comparator) on the one hand, and can be switched between a reference potential and a predefined reference voltage on the other; wherein the input switch is a power field-effect transistor of a switched power converter circuit.

In Example 26, the subject matter of Example 25 can optionally provide that the switched capacitor converter (e.g. analog-to-digital converter) further comprises an input pad for applying an analog input voltage; wherein a first terminal of the input capacitor is continuously electrically conductively connected to the input pad, and wherein a second terminal of the input capacitor is electrically conductively connected to an amplifier input (for example comparator).

In Example 27, the subject matter of Example 26 can optionally have a switch-free connection between the first terminal of the input capacitor and the input pad.

In Example 28, the subject matter of any of Examples 25 to 27 can optionally provide that the switched capacitor circuit is set up to switch synchronously with the voltage curve of a voltage at the power field-effect transistor.

In Example 29, the subject matter of any of Examples 25 to 28 can optionally provide that the switched capacitor converter (e.g. analog-digital converter) further comprises a bias voltage switch which is connected between an amplifier input (e.g. comparator) and a bias voltage terminal and is set up to receive a bias voltage.

In Example 30, the subject matter of Example 29 can optionally provide that the switched capacitor converter (e.g. analog-digital converter) further comprises a first switch controller, which is set up to close the bias voltage switch in an initialization phase, so that the bias voltage is applied to the amplifier input (e.g. comparator), and to open the bias voltage switch in a measuring phase, so that the amplifier input (for example comparator) is isolated from the bias voltage.

In Example 31, the subject matter of any of Examples 25 to 30 can optionally provide that the switched capacitor converter (e.g. analog-digital converter) further comprises a second switch controller which is set up to switch the switched capacitor circuit depending on the voltage curve of a voltage at the power field-effect transistor.

In Example 32, the subject matter of Example 31 can optionally provide that the second switch controller is set up to connect the switched capacitor circuit to the reference potential in an initialization phase and to connect the switched capacitor circuit to the reference voltage in a measuring phase.

In Example 33, the subject matter of any of the Examples 31 or 32 can optionally provide that the second switch controller is set up to provide the input voltage according to an equilibrium state of the power field-effect transistor, so that in a first equilibrium state of the power field-effect transistor, the switched capacitor circuit is connected to the reference potential and that in a second equilibrium state of the power field-effect transistor, the switched capacitor circuit is connected to the reference voltage.

In Example 34, the subject matter of Examples 32 and 33 can optionally provide that the second switch controller is set up to terminate an initialization phase of the switched capacitor circuit and to start the measuring phase synchronously with the second equilibrium state of the power field-effect transistor in which the power field-effect transistor is conductively switched.

In Example 35, the subject matter of any of Examples 25 to 34 can optionally provide that the switched capacitor converter (e.g. analog-digital converter) further comprises a memory element which is connected to an output of the amplifier (e.g. comparator) for storing a digital signal output from the amplifier (e.g. comparator).

In Example 36, the subject matter of any of the Examples 25 to 35 can optionally provide that the switched capacitor circuit has at least one capacitor and a switch, wherein a first terminal is connected to an amplifier input (for example comparator) and a second terminal is connected to the switch, wherein the switch can be switched between a reference potential and the reference voltage.

Example 37 is a power converter. The power converter can comprise a switched capacitor converter (e.g. analog-to-digital converter) according to any of the Examples 1 to 36; and at least one field-effect transistor, for example at least one field-effect transistor, for example at least one power field-effect transistor, which is connected to the switched capacitor converter (e.g. analog-to-digital converter). It should be noted that at least one field-effect transistor can be any field-effect transistor, e.g. a GaN field-effect transistor. Furthermore, the at least one transistor can also be connected to the switched capacitor converter (e.g. analog-digital converter) via additional circuit components, e.g. via an inductor (e.g. the inductor 102 from FIG. 1, FIG. 2 or FIG. 5), for example a coil (e.g. the coil 102 from FIG. 1, FIG. 2 or FIG. 5).

In Example 38, the subject matter of Example 37 can optionally provide that the power converter further comprises a bridge circuit comprising at least two power field-effect transistors.

In Example 39, the subject matter of Example 38 can optionally provide that the bridge circuit is configured as a half-bridge circuit or as a full-bridge circuit.

In Example 40, the subject matter of any of Examples 37 to 39 can optionally provide that the power converter further comprises a gate driver circuit for providing a gate voltage to a gate terminal of at least one transistor, for example, a field-effect transistor, for example, a power field-effect transistor.

In Example 41, the subject matter of any of Examples 37 to 40 can optionally provide that the power converter further comprises at least one inductor, which is switched between the at least one transistor, for example a field-effect transistor, for example a power field-effect transistor, and an output terminal of the power converter.

In Example 42, the subject matter of any of Examples 37 to 41 can optionally provide that the power converter further comprises a processor which is set up to generate a switching signal for switching the switched capacitor circuit, depending on a digital signal provided by the switched capacitor converter (e.g. analog-digital converter).

In Example 43, the subject matter of Example 42 can optionally provide that the processor is set up as a pulse width modulation controller.

In Example 42, the subject matter of any of Examples 1 to 43 can optionally provide that the switched capacitor converter (e.g. analog-to-digital converter) is configured as a comparator. In other words, the switched capacitor converter (e.g. analog-digital converter) can be configured as a 1-bit switched capacitor converter (e.g. 1-bit analog-digital converter).

What is claimed is:

1. A switched capacitor converter, comprising:
an input pad for applying an analog input voltage;
an amplifier;
an input capacitor having a first terminal and a second terminal, the first terminal of the input capacitor being continuously electrically conductively connected to the input pad, and the second terminal of the input capacitor being electrically conductively connected to an input of the amplifier; and
a switched capacitor circuit, which is electrically conductively connected to the input of the amplifier in a first mode, and can be switched between a reference potential and a predefined reference voltage on in a second mode.

2. The switched capacitor converter as claimed in claim 1,
wherein the connection between the first terminal of the input capacitor and the input pad is switch-free.

3. The switched capacitor converter as claimed in claim 1,
wherein the switched capacitor circuit is synchronized with the analog input voltage.

4. The switched capacitor converter as claimed in claim 1,
wherein the analog input voltage depends on a voltage at a power field-effect transistor of a switched power converter circuit.

5. The switched capacitor converter as claimed in claim 1, further comprising: a bias voltage switch, which is connected between the input of the amplifier and a bias voltage terminal, and is configured to receive a bias voltage.

6. The switched capacitor converter as claimed in claim 5, further comprising: a first switch controller, which is configured to close the bias voltage switch in an initialization phase so that the bias voltage is applied to the input of the amplifier, and to open the bias voltage switch in a measuring phase so that the input of the amplifier is isolated from the bias voltage.

7. The switched capacitor converter as claimed in claim 1, further comprising:
a second switch controller, which is configured to switch the switched capacitor circuit for setting a threshold voltage of the amplifier,
wherein the second switch controller is optionally configured to connect the switched capacitor circuit to the reference potential in an initialization phase and to connect the switched capacitor circuit to the predefined reference voltage in a measuring phase.

8. The switched capacitor converter as claimed in claim 1, wherein the switched capacitor converter is configured as an analog-to-digital converter, and further comprising:
a latch connected to an output of the amplifier to form a comparator.

9. A switched capacitor converter, comprising:
an amplifier;
an input capacitor connected to an input of the amplifier, which is further connected to an analog input voltage; and
a switched capacitor circuit, which is connected to the input of the amplifier in a first mode and can be switched between a reference potential and a predefined reference voltage in a second mode,
wherein the switched capacitor circuit is configured to switch depending on a voltage curve of a voltage at a power field-effect transistor of a switched power converter circuit.

10. The switched capacitor converter as claimed in claim 9, further comprising:
an input pad for applying the analog input voltage,
wherein a first terminal of the input capacitor is continuously electrically conductively connected to the input pad, and wherein a second terminal of the input capacitor is electrically conductively connected to an amplifier input.

11. The switched capacitor converter as claimed in claim 10,
wherein the connection between the first terminal of the input capacitor and the input pad is switch-free.

12. The switched capacitor converter as claimed in claim 9,
wherein the switched capacitor circuit is configured to switch synchronously with the voltage curve of the voltage at the power field-effect transistor.

13. The switched capacitor converter as claimed in claim 9, further comprising:
a bias voltage switch, which is connected between an amplifier input and a bias voltage terminal and is configured to receive a bias voltage.

14. The switched capacitor converter as claimed in claim 13, further comprising:
a first switch controller, which is configured to close the bias voltage switch in an initialization phase so that the bias voltage is applied to the amplifier input, and to open the bias voltage switch in a measuring phase so that the amplifier input is isolated from the bias voltage.

15. The switched capacitor converter as claimed in claim 9, further comprising:
a second switch controller, which is configured to switch the switched capacitor circuit for setting a threshold voltage of the amplifier,
optionally wherein the second switch controller is configured to connect the switched capacitor circuit to the reference potential in an initialization phase and to connect the switched capacitor circuit to the predefined reference voltage in a measuring phase.

16. The switched capacitor converter as claimed in claim 9, wherein the switched capacitor converter is configured as an analog-to-digital converter, and further comprising:
a latch connected to an output of the amplifier to form a comparator.

17. A power converter, comprising:
a first transistor including a first terminal, a second terminal, and a control terminal;
a second transistor including a first terminal, a second terminal, and a control terminal, the first terminal of the second transistor coupled to the second terminal of the first transistor;
a gate driver circuit coupled to the control terminal of the first transistor and coupled to the control terminal of the second transistor;
a capacitor having a first terminal and a second terminal, the first terminal of the capacitor coupled to the second terminal of the first transistor and the first terminal of the second transistor;
an amplifier having an input terminal and an output terminal, the input terminal of the amplifier coupled to the second terminal of the capacitor; and
a switched capacitor circuit, comprising:
a plurality of capacitors arranged in parallel, wherein each capacitor of the plurality of capacitors has a first terminal coupled to the input terminal of the amplifier; and
a plurality of switches coupled to respective second terminals of the plurality of capacitors, respectively, wherein the plurality of switches are configured to couple the second terminals of the capacitors to a first reference voltage when a first control signal is in a first state, and to a second reference voltage that differs from the first reference voltage when the first control signal is in a second state.

18. The power converter of claim 17, further comprising:
a bias voltage switch having a control terminal, a first terminal, and a second terminal, the first terminal of the bias voltage switch coupled to a DC bias voltage terminal, and the second terminal of the bias voltage switch coupled to the input terminal of the amplifier.

19. The power converter of claim 18, wherein the control terminal of the bias voltage switch is coupled to the control terminal of the first transistor and/or the control terminal of the second transistor.

20. The power converter of claim 18, wherein the bias voltage switch is switched synchronously with the first transistor and/or the second transistor, and wherein there is an absence of a switch between the first terminal of the capacitor and the second terminal of the first transistor.
